(19) United States
(12) Patent Application Publication
(10) Pub. No.: US 2008/0254613 A1
(43) Pub. Date: Oct. 16, 2008

(54) METHODS FOR FORMING METAL INTERCONNECT STRUCTURE FOR THIN FILM TRANSISTOR APPLICATIONS

(75) Inventors: Yanping Li, Mountain View, CA (US); Hien-Minh Le, San Jose, CA (US); Hong Zhang, Fremont, CA (US); Jenn Yue Wang, Fremont, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 11/733,203

(22) Filed: Apr. 10, 2007

(51) Int. Cl. H01L 21/4763

(52) U.S. Cl. 438/624; 257/E21.495

(57) ABSTRACT

Methods for forming a metal interconnection structure in thin-film transistor applications are provided in the present invention. In one embodiment, the method may include providing a substrate into a processing chamber, supplying a first gas mixture into the chamber to deposit a metal layer on the substrate, and supplying a second gas mixture into the chamber to deposit a barrier layer on the metal layer. In another embodiment, a metal interconnection structure may include a substrate, a first barrier layer disposed on the substrate, a metal layer disposed on the substrate in a processing chamber, a second barrier layer disposed on the metal layer formed in the processing chamber a second barrier layer disposed on the metal layer formed in the processing chamber, wherein the first barrier layer, the metal layer and the second barrier layer are configured to form a metal interconnection structure for TFT devices.

### BACKGROUND OF THE DISCLOSURE

1. Field of the Invention

The present invention relates to methods for forming a metal interconnection structure, more specifically, for forming a metal interconnection structure for thin film transistor applications.

2. Description of the Background Art

Plasma display panels and liquid crystal displays are frequently used for flat panel displays. Liquid crystal displays (LCD) generally contain two glass substrates joined together with a layer of a liquid crystal material sandwiched therebetween. The glass substrate may be a semiconductor substrate, or may be a transparent substrate such as a glass, quartz, sapphire, or a clear plastic film. The LCD may also contain light emitting diodes for back lighting. Furthermore, organic light emitting diodes (OLEDs) having been used for liquid crystal displays, and these organic light emitting diodes require thin film transistors (TFTs) for addressing the activity of the displays.

FIG. 1 illustrates a cross sectional schematic view of a back channel etched (BCE) thin film transistor (TFT) 100 conventionally used in the art. The transistor 100 includes a gate electrode layer 102 disposed on a substrate 101 where the substrate 101 is optically transparent in the visible spectrum. The gate electrode layer 102 is an electrically conductive layer that controls the movement of charge carriers within the transistor. Suitable materials for fabricating the gate electrode layer 102 may include aluminum (Al), tungsten (W), chromium (Cr), tantalum (Ta), molybdenum (Mo), or combination thereof. The gate electrode layer 102 may be a single metal layer or a two or more metal layers stacked film to prevent metal diffusion to adjacent layers. The gate electrode layer 102 is subsequently lithographically patterned and etched using conventional techniques to define a desired pattern of the gate electrode layer 102.

An insulating gate dielectric layer 104, such as silicon oxide (SiO₂), silicon oxynitride (SiON), or silicon nitride (SiN), is formed on the gate electrode layer 102. A bulk semiconductor layer 106 is formed on the gate dielectric layer 104. Suitable materials for the bulk semiconductor layer 106 include polycrystalline silicon (polysilicon) and amorphous silicon (a-Si). A doped semiconductor layer 110 is formed on the bulk semiconductor layer 106. The doped semiconductor layer 110 may include n-type or p-type doped polycrystalline (polysilicon) or amorphous silicon (a-Si). The bulk semiconductor layer 106 and the doped semiconductor layer 110 are lithographically patterned and etched using conventional techniques to define a channel 114 on these two films over the gate dielectric layer 104, which serves as storage capacitor dielectric. The doped semiconductor layer 110 is in direct contact with portions of bulk semiconductor layer 106, forming a semiconductor junction.

A conductive layer 108 is formed on the exposed surface of the bulk semiconductor layer 106 and the doped semiconductor layer 110. The conductive layer 108 and the doped semiconductor layer 110 may be patterned to define source and drain contacts of the transistor 100. The conductive layer 108 may be fabricated by a conductive material similar to the gate electrode layer 102, such as aluminum (Al), tungsten (W), molybdenum (Mo), chromium (Cr), tantalum (Ta), and combination thereof. A passivation layer 112 is then conformably coated the exposed surfaces. The insulating gate dielectric layer 104, the bulk semiconductor layer 106, the doped semiconductor layer 110 and the passivation layer 112 may be formed by conventional plasma enhanced chemical vapor deposition process (PECVD) and the gate electrode layer 102 and the conductive layer 108 may be formed by conventional depositing techniques, such as sputtering.

FIG. 2 depicts an enlarged partial sectional view of an exemplary embodiment of the gate electrode layer 102 in form of a triple layer film stack disposed on the substrate 101. The triple layer film stack has an aluminum layer (Al) 206 sandwiched between an upper and lower molybdenum (Mo) layers 208, 210. The upper and lower molybdenum (Mo) layers 208, 210 serve as barrier layers, capping the aluminum layer 206 to prevent aluminum layer 206 from forming hillocks or diffusing to the adjacent dielectric layer when exposed to high temperatures during the subsequent dielectric layer deposition process. However, the high temperature of the dielectric layer deposition process may disadvantageously induce reactions between the interface of the aluminum layer 206 and molybdenum (Mo) layers 208, 210, causing an Al—Mo alloy 212, 214 to be formed at the interface. The Al—Mo alloy 212, 214 may increase roughness of the aluminum layer 206 and create undesired aluminum grain boundary, thereby increasing contact resistance of the TFT device.

Additionally, the aluminum layer 206 and molybdenum layer 208, 210 have different selectivity to etchants, thereby causing poor etch results. The poor selectivity between the aluminum layer 206 and molybdenum layer 208, 210 may result in tapered or undercut defects in the gate electrode layer 102, which is detrimental to transistor performance.

Therefore, there is a need for an improved method for forming a metal interconnection structure in thin-film transistor applications.

### SUMMARY OF THE INVENTION

Methods for forming a metal interconnect structure in thin-film transistor applications are provided in the present invention. In one embodiment, the method for forming a metal interconnection structure may include providing a substrate configured to form a metal interconnection structure for TFT devices thereon into a processing chamber, supplying a first gas mixture into the chamber to deposit a metal layer on the substrate, and supplying a second gas mixture into the chamber to deposit a barrier layer on the metal layer.

In another embodiment, a method for forming a metal interconnect layer in thin-film transistor applications may include providing a substrate into a processing chamber, supplying a first gas mixture into the chamber, sputtering source material from a target disposed in the processing chamber using the first gas mixture, reacting the sputtered material with the first gas mixture to form a metal layer on the substrate, supplying a second gas mixture into the chamber, sputtering source material from the target disposed in the processing chamber using the second gas mixture, and reacting the sputtered material with the second gas mixture to form a barrier layer on the metal layer.

In yet another embodiment, a metal interconnection structure utilized to form a gate electrode layer in a thin-film transistor may include a substrate, a first barrier layer disposed on the substrate, a metal layer disposed on the substrate in a processing chamber, a second barrier layer disposed on the metal layer formed in the processing chamber, wherein the first barrier layer, the metal layer and the second barrier layer are configured to form a metal interconnection structure for TFT devices.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic cross-sectional view of a back channel etched (BCE) thin film transistor (TFT) 100 conventionally used in the art;

FIG. 2 depicts an enlarged partial sectional view of an exemplary embodiment of the gate electrode layer in form of a triple layer film stack of the TFT of FIG. 1;

FIG. 3 depicts a schematic cross-sectional view of one embodiment of a process chamber suitable for practicing the invention;

FIG. 4 depicts a process flow diagram for forming a metal interconnection layer in accordance with one embodiment of the present invention;

FIG. 5 depicts a schematic cross-sectional view of a substrate having film stack utilized to form a metal interconnection structure disposed thereon in accordance with an embodiment in the present invention;

FIG. 6 depicts a top plan view of one embodiment of a cluster system 600 that may be used to perform one embodiment of the present invention; and

FIG. 7 depicts a top plan view of another embodiment of a cluster system 700 that may be used to perform one embodiment of the present invention.

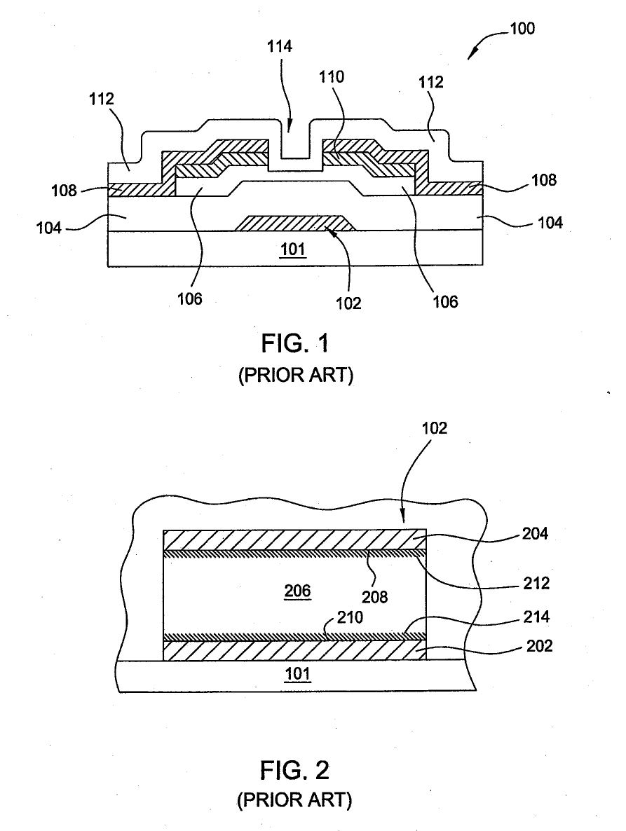

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Methods for forming a metal interconnection structure in thin-film transistor applications are provided in the present invention. The methods produce a film stack for a metal interconnection structure having good etching selectivity, low contact resistance, and good surface roughness which is suitable for thin-film transistor applications. Examples of the metal interconnection structure may include a gate electrode layer, a conductive layer utilized to form a source/drain contact, or any other metallic structure employed in a thin film transistor device. In one embodiment, the metal interconnection structure may include a film stack having an aluminum nitride (AlN) layer formed on an aluminum (Al) layer disposed on a molybdenum (Mo) layer utilized to form a gate electrode layer on a substrate. The aluminum nitride (AlN) layer serves as a barrier layer, preventing the underlying aluminum layer from forming hillocks and alloys while controlling surface roughness, which improves the electrical performance of the film stack and devices formed therefrom, such as TFT devices and the like. In another embodiment, the metal interconnection structure may include a film stack having an aluminum layer sandwiched by an upper aluminum nitride (AlN) barrier and a lower aluminum nitride (AlN) barrier layer which prevent the aluminum layer from coming in direct contact with the underlying substrate and the upper adjacent dielectric layers, thereby reducing interface diffusion contamination between the layers. The film stack may be disposed on a substrate with or without a molybdenum (Mo) layer disposed thereon.

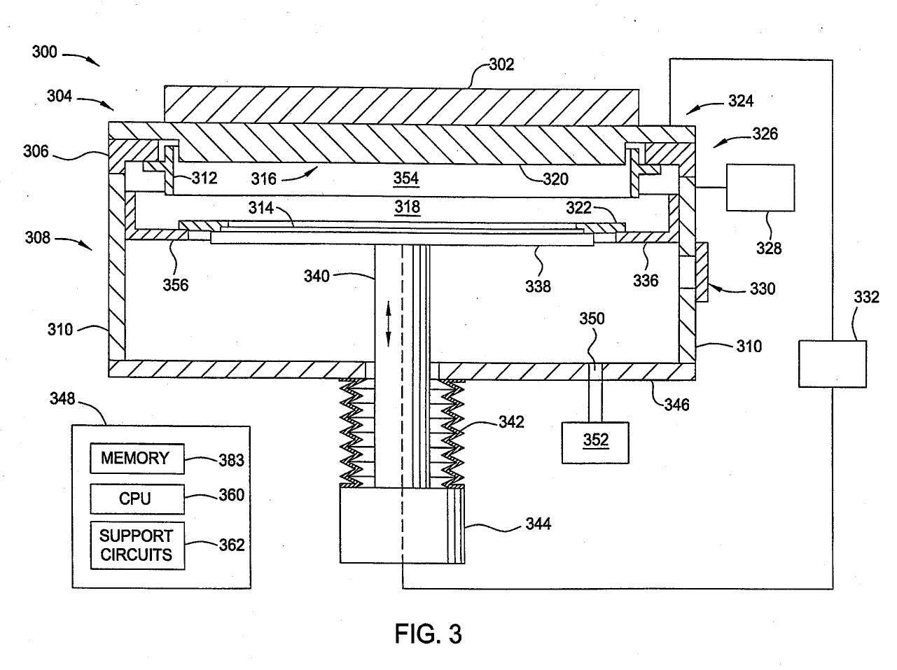

FIG. 3 illustrates an exemplary reactive sputter process chamber 300 suitable for sputter depositing a metal interconnection structure according to one embodiment of the invention. One example of the process chamber that may be adapted to benefit from the invention is a PVD process chamber, available from Applied Materials, Inc., located in Santa Clara, Calif. It is contemplated that other sputter process chambers, including those from other manufactures, may be adapted to practice the present invention.

The process chamber 300 includes a chamber body 308 having a processing volume 318 defined therein and enclosed by a lid assembly 304. The chamber body 308 has sidewalls 310 and a bottom 346. The dimensions of the chamber body 308 and related components of the process chamber 300 are not limited and generally are proportionally larger than the size of a substrate 314 to be processed. Any suitable substrate size may be processed therein. Examples of suitable substrate sizes include substrates having a surface area of about 2000 or more square centimeters.

The chamber body 308 may be fabricated from aluminum or other suitable material. A substrate access port 330 is formed through the sidewall 310 of the chamber body 308, facilitating the transfer of the substrate 314 (i.e., a solar panel or a flat panel display glass substrate, a semiconductor wafer, or other workpiece) into and out of the process chamber 300. The access port 330 may be coupled to a transfer chamber and/or other chambers of a substrate processing system.

A gas source 328 is coupled to the chamber body 308 to supply process gases into the processing volume 318. Examples of process gases that may be provided by the gas source 328 include inert gases, non-reactive gases, and reactive gases. In one embodiment, process gases provided by the gas source 328 may include, but not limited to, argon gas (Ar), helium (He), nitrogen gas (N₂), oxygen gas (O₂), and H₂O, among others.

A pumping port 350 is formed through the bottom 346 of the chamber body 308. A pumping device 352 is coupled to the process volume 318 to evacuate and control the pressure therein. In one embodiment, the pressure level of the process chamber 300 may be maintained at about 1 Torr or less.

The lid assembly 304 generally includes a target 320 and a ground shield assembly 326 coupled or positioned proximate thereto. The target 320 provides a material source that can be sputtered and deposited onto the surface of the substrate 314 during a PVD process. The target 320 or target plate may be fabricated from a material utilized as a deposition specie. A high voltage power supply, such as a power source 332, is connected to the target 320 to facilitate sputtering materials from the target 320. In one embodiment, the target 120 may be fabricated from a material containing aluminum (Al) metal. In another embodiment, the target 320 may be fabricated by materials including aluminum alloy and the like.

The target 320 generally includes a peripheral portion 324 and a central portion 316. The peripheral portion 324 is disposed over the sidewalls 310 of the chamber. The central portion 316 of the target 320 may have a curvature surface slightly extending towards the surface of the substrate 314 disposed on a substrate support 338. The spacing between the target 320 and the substrate support 338 is maintained between about 50 mm and about 150 mm. It is noted that the dimension, shape, materials, configuration and diameter of the target 320 may be varied for specific process or substrate requirements. In one embodiment, the target 320 may further include a backing plate having a central portion bonded and/or fabricated from a material desired to be sputtered onto the substrate surface. The target 320 may also include a plurality of tiles or segment materials that together form the target.

The lid assembly 304 may further comprise a magnetron assembly 302 mounted above the target 320 which enhances efficient sputtering of material from the target 320 during processing. Examples of the magnetron assembly include a linear magnetron, a serpentine magnetron, a spiral magnetron, a double-digitated magnetron, a rectangularized spiral magnetron, among others.

The ground shield assembly 326 of the lid assembly 304 includes a ground frame 306 and a ground shield 312. The ground shield assembly 326 may also include other chamber shield members, target shield member, dark space shield, and dark space shield frame. The ground shield 312 is coupled to the peripheral portion 324 by the ground frame 306 defining an upper processing region 354 below the central portion 316 of the target 320 in the process volume 318. The ground frame 306 electrically insulates the ground shield 312 from the target 320 while providing a ground path to the chamber body 308 of the process chamber 300 through the sidewalls 310. The ground shield 312 constrains plasma generated during processing within the upper processing region 354 so that dislodged target source material from the central portion 316 of the target 320 is mainly deposited on the substrate surface rather than chamber sidewalls 310. In one embodiment, the ground shield 312 may be formed by one or more components.

A shaft 340, that extends through the bottom 346 of the chamber body 308, couples to the substrate support 338 to a lift mechanism 344. The lift mechanism 344 is configured to move the substrate support 338 between a lower transfer position and an upper processing position. A bellows 342 circumscribes the shaft 340 and coupled to the substrate support 338 to provide a flexible seal therebetween, thereby maintaining vacuum integrity of the chamber processing volume 318.

A shadow frame 322 is disposed on the periphery region of the substrate support 338 and is configured to confine deposition of source material sputtered from the target 320 to a desired portion of the substrate surface. When the substrate support 338 is in a lowered position, the shadow frame 322 is suspended above the substrate support 338 from a lip 356 of a chamber shield 336 that extends from the inner wall of the chamber body 308. As the substrate support 338 is raised to the upper position for processing, an outer edge of the substrate 314 disposed on the substrate support 338 contacts by the shadow frame 322, causing the shadow frame 322 to be lifted and spaced away from the chamber shield 336. Lift pins (not shown) are selectively moved through the substrate support 338 to lift the substrate 314 above the substrate support 338 to facilitate access to the substrate 314 by a transfer robot or other suitable transfer mechanism.

A controller 348 is coupled to the process chamber 300. The controller 348 includes a central processing unit (CPU) 360, a memory 358, and support circuits 362. The controller 348 is utilized to control the process sequence, regulating the gas flows from the gas source 328 into the chamber 300 and controlling ion bombardment of the target 320. The CPU 360 may be of any form of a general purpose computer processor that can be used in an industrial setting. The software routines can be stored in the memory 358, such as random access memory, read only memory, floppy or hard disk drive, or other form of digital storage. The support circuits 362 are conventionally coupled to the CPU 360 and may comprise cache, clock circuits, input/output subsystems, power supplies, and the like. The software routines, when executed by the CPU 360, transform the CPU into a specific purpose computer (controller) 348 that controls the process chamber 300 such that the processes are performed in accordance with the present invention. The software routines may also be stored and/or executed by a second controller (not shown) that is located remotely from the chamber 300.

During processing, the target 320 and the substrate support 338 are biased relative to each other by the power source 332 to maintain a plasma formed from the process gases supplied by the gas source 328. The ions from the plasma are accelerated toward and strike the target 320, causing target material to be dislodged from the target 320. The dislodged target material forms a layer on the substrate 314. In embodiments where certain process gases are supplied into the chamber 300, the dislodged target material and the process gases present in the chamber 300 react to forms a composite film on the substrate 314.

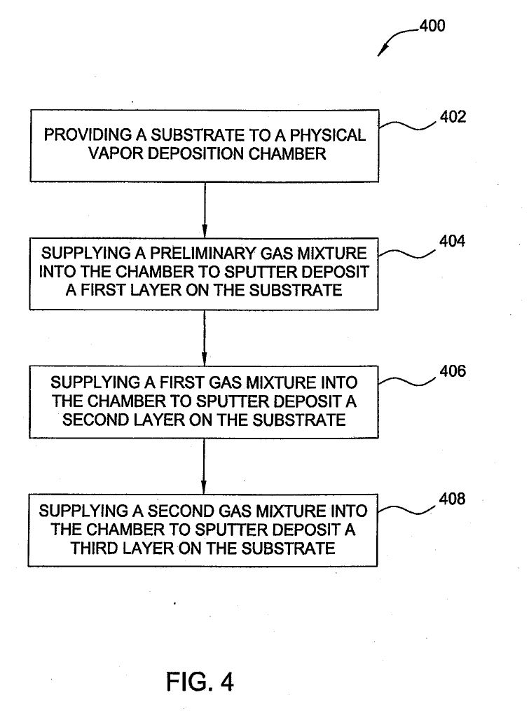

FIG. 4 depicts a flow diagram of one embodiment of a sputtering deposition process 400 for forming a metal interconnection structure on a substrate. The process 400 may be stored in the memory 358 as instructions that when executed by the controller 348, cause the process 400 to be performed in the process chamber 300 or other suitably configured tools, including those from other manufacturers.

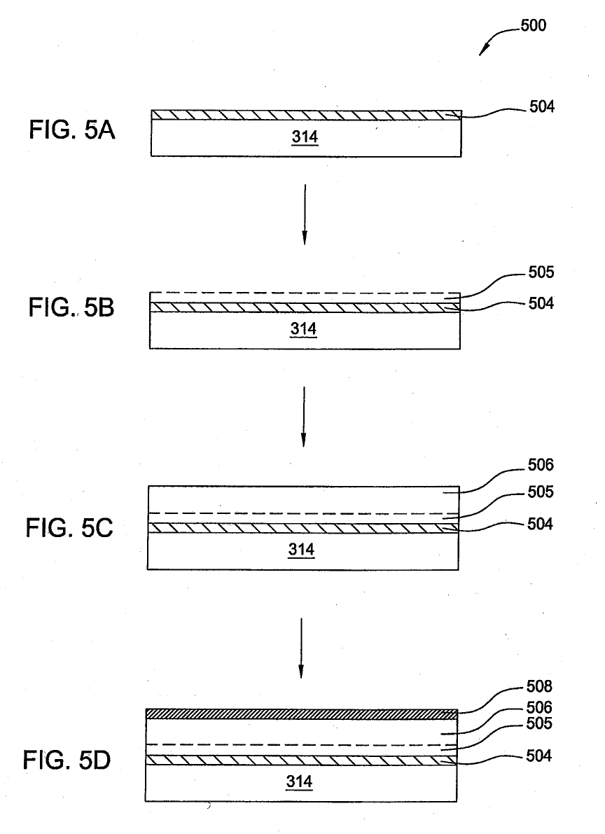

FIGS. 5A-5C are schematic, cross-sectional views corresponding to different stages of the process 400. The reader should refer to both FIGS. 3 and 5A-C for best understand of the description of the process 400 that follows.

The process 400 begins at step 402 by providing a substrate 314 in a process chamber, such as the processing chamber 300 of FIG. 3. In one embodiment, the substrate 314 is substrate for forming a metal interconnection structure. The metal interconnection structure may be utilized to form a gate electrode layer or a conductive layer for forming source/drain contact in TFT applications, among other applications. The substrate 314 includes a barrier layer 504 pre-disposed thereon, as shown in FIG. 5A. The barrier layer 504 prevents the subsequently layers disposed thereon to be in direct contact with the substrate 314. In one embodiment, the pre-disposed barrier layer 504 may be deposited on the substrate 314 by any suitable manners. In one embodiment, the pre-disposed barrier layer 504 may be deposited in a physical vapor deposition chamber, such as the chamber 300 described in FIG. 3. The pre-disposed barrier layer 504 may be a metal layer selected from a group consisting of molybdenum (Mo), chromium (Cr), titanium (Ti), tantalum (Ta), tungsten (W), zinc (Zn), tin (Sn), alloys of these materials, and combination thereof. Alternatively, the pre-disposed barrier layer 504 may be a dielectric layer, such as molybdenum nitride, chromium nitride, titanium nitride, tantalum nitride, tungsten nitride, aluminum nitride, zinc nitride, and the like. In embodiments where the pre-disposed barrier layer 504 is not present, the process 400 may be performed directly on the substrate 314.

In one embodiment, the substrate 314 refers to any substrate or material surface upon which film processing is performed. For example, the substrate 314 may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire or other suitable workpeices. The substrate 314 may have various dimensions, as well as circular, rectangular or square profiles.

At optional step 404, a preliminary gas mixture may be optionally supplied into the processing chamber 300. The preliminary gas mixture includes at least a reactive gas. In one embodiment, the reactive gas supplied in the preliminary gas mixture includes a nitrogen containing gas. Examples of nitrogen containing gas include N₂, N₂O, NO₂, NH₃, and the like. An inert gas may be supplied with the reactive gas to carry the reactive gas to the substrate surface. Examples of the inert gas include Ar, He, Kr and the like. The nitrogen containing gas in the preliminary gas mixture is plasma dissociated in the process chamber 300 and reacts with the source material sputtered from the target 320, forming a metallic nitride layer as the optional barrier layer 505 on the substrate 314, as shown in FIG. 5B.

In certain embodiments of the present invention, the optional barrier layer 505 may be deposited as different types of metallic nitride layers. Examples of the target materials include Al, Mo, Cr, Ta, Ti, or W. During sputtering, a RF bias power is applied between the target 320 and the substrate support 338 maintains a plasma formed from the preliminary gas mixture in the process chamber 300. The ions from the preliminary gas mixture in the plasma bombard and sputter off material from the target 320. The preliminary gas mixture carrier the sputtered material from the target 320 to the substrate surface to form the optional barrier layer 505. The gas mixture and/or other process parameters may be varied during the sputtering deposition process, thereby adjusting different film properties of the barrier layer 505 to meet different process requirements.

In embodiments wherein an aluminum containing material is utilized as the source material for the target 320, the nitrogen containing reactive gas supplied in the preliminary gas mixture reacts with aluminum sputtered from the target 320, forming an aluminum nitride layer as the optional barrier layer 505 on the substrate 314. The optional aluminum nitride barrier layer 505 prevents underlying pre-disposed barrier layer 504 from in direct contact with the following deposited layer, thereby preventing alloy and/or unwanted interfacial layer formation at the interface as compared to conventional structures. In embodiment where the optional barrier layer 505 is deposited and utilized in the gate structure, the underlying pre-disposed barrier layer 504 may be eliminated as needed. In one embodiment, the nitrogen element contained in the aluminum nitride barrier layer 505 may have a ratio between about 5 percent by atomic weight and about 30 percent by atomic weight, for example, about 10 percent by atomic weight.

In one embodiment, the reactive gas and inert gas supplied in the preliminary gas mixture are N₂ gas and Ar gas respectively. The N₂ gas may be supplied at a flow rate between about 30 sccm and about 180 sccm, such as between about 45 sccm and about 120 sccm, for example between about 60 scorn and about 90 sccm. Alternatively, N₂ gas flow may be controlled at a flow rate per chamber volume between about 0 sccm per chamber volume (sccm/Liter) and about 6 sccm per chamber volume (sccm/Liter), such as between about 0.5 sccm per chamber volume (sccm/Liter) and about 2 sccm per chamber volume (sccm/Liter), for example between about 1 sccm per chamber volume (sccm/Liter) and about 1.5 sccm per chamber volume (sccm/Liter). The Ar gas may be supplied at a flow rate between about 50 sccm and about 300 sccm, such as between about 75 sccm and about 200 sccm, for example between about 100 sccm and about 150 sccm. Alternatively, Ar gas flow may be controlled at a flow rate per chamber volume between about 1 sccm per chamber volume (sccm/Liter) and about 6 sccm per chamber volume (sccm/Liter), such as between about 1.6 sccm per chamber volume (sccm/Liter) and about 4 sccm per chamber volume (sccm/Liter), for example between about 2 sccm per chamber volume (sccm/Liter) and about 3 sccm per chamber volume (sccm/Liter).

Several process parameters may be regulated at step 404 while supplying the preliminary gas mixture. In one embodiment, a pressure of the preliminary gas mixture in the process chamber 300 is regulated between about 0 mTorr and about 100 mTorr, such as between about 1 mTorr and about 10 mTorr. The substrate temperature may be maintained between about 100 degrees Celsius and about 400 degrees Celsius, such as between about 150 degrees Celsius and about 300 degrees Celsius. The DC power may be supplied between about 0 milliWatts per centimeter square and about 100 milliWatts per centimeter square, such as between about 3 milliWatts per centimeter square and about 20 milliWatts per centimeter square, for example, about 5 milliWatts per centimeter square and about 15 milliWatts per centimeter square.

At step 406, a first gas mixture is supplied into the processing chamber 300 to form a metallic layer 506 on the substrate 314, as shown in FIG. 5C. The first gas mixture serves as a carrier gas to assist gas flow circulation and transportation of the source material sputtered from the target 320 to the substrate surface. In one embodiment, the first gas mixture may be supplied into the processing chamber 300 may include at least one inert gas, such as Ar, He, or Kr.

In one embodiment, the first gas mixture may include Ar gas or He gas. In embodiments where an Ar gas is supplied in the first gas mixture, the Ar gas may be supplied at a flow rate between about 50 sccm and about 300 sccm, such as between about 80 sccm and about 200 sccm, for example between about 100 sccm and about 150 sccm. Alternatively, Ar gas flow may be controlled at a flow rate per chamber volume between about 1 sccm per chamber volume (sccm/Liter) and about 6 sccm per chamber volume (sccm/Liter), such as between about 1.6 sccm per chamber volume (sccm/Liter) and about 4 sccm per chamber volume (sccm/Liter), for example between about 2 sccm per chamber volume (sccm/Liter) and about 3 sccm per chamber volume (sccm/Liter).

During sputter depositing, several process parameters may be regulated at step 406 while supplying the first gas mixture. In one embodiment, a pressure of the first gas mixture in the process chamber 300 is regulated between about 0 mTorr and about 100 mTorr, such as between about 1 mTorr and about 10 mTorr. The substrate temperature may be maintained between about 100 degrees Celsius and about 400 degrees Celsius, such as between about 150 degrees Celsius and about 300 degrees Celsius. The DC power may be supplied between about 0 milliWatts per centimeter square and about 100 milliWatts per centimeter square, such as between about 3 milliWatts per centimeter square and about 20 milliWatts per centimeter square, for example, about 5 milliWatts per centimeter square and about 15 milliWatts per centimeter square.

In embodiments where the optional step 404 is performed to form the optional barrier layer 505 on the substrate 314, the process parameters regulated at optional step 404 may be smoothly transited into the parameters regulated at step 406. Alternatively, the process parameters and gas flow rate may be controlled substantially the same in both steps 404, 406, except the reactive gas present in the preliminary gas mixture at step 404 is eliminated in the first gas mixture at step 406. The transition between steps 406, 408 may be alternatively configured. The reactive gas supplied at optional step 404 facilitates integratedly depositing the optional barrier layer 505 and the metal layer 506 within a singe processing chamber, thereby reducing manufacturing cost and overall process time. Additionally, as the optional barrier layer 505 and the metal layer 506 are both formed from the same target source material, the two films 505, 506 are highly comparable to each other, thereby providing a good adhesion at their interface.

The processing time may be processed at a predetermined processing period or after a desired thickness of the metal layer 506 is deposited on the substrate 314. In one embodiment, the process time may be processed at between about 5 seconds and about 120 seconds, such as between about 15 seconds to about 60 seconds. In another embodiment, the process time may be processed and terminated as the thickness of the metal layer 506 has reached. In one embodiment, the thickness of the metal layer 506 is between about 2000 Å and about 8000 Å. The processing parameters described above may be tailored for different substrate sizes.

At step 408, a second gas mixture is supplied into the processing chamber 300 to sputter deposit a barrier layer 508 on the metal layer 506, as shown in FIG. 5D. The second gas mixture includes at least a reactive gas which is not present in the first gas mixture. An inert gas may be supplied with the reactive gas to carry the reactive gas to the substrate surface. Examples of the inert gas include Ar, He, Kr and the like. The reactive gas in the second gas mixture reacts with the source material sputtered from the target 320, thereby forming the barrier layer 508 on the substrate 314. In embodiments where the optional step 404 is performed to form the optional barrier layer 505 on the substrate 314, the second gas mixture supplied at the step 408 may be substantially the same as the preliminary gas mixture supplied at the step 404. Accordingly, the barrier layer 508 deposited on the metal layer 506 may be substantially the same as the optional barrier layer 505 formed on the substrate 314.

In one embodiment, the reactive gas supplied in the second gas mixture includes a nitrogen containing gas. Examples of nitrogen containing gas include N₂, N₂O, NO₂, NH₃, and the like.

In embodiments wherein an aluminum containing material is utilized as the source material for the target 320, the nitrogen containing reactive gas supplied in the second gas mixture reacts with aluminum sputtered from the target 320, forming an aluminum nitride layer as the barrier layer 508 on the substrate 314. The aluminum nitride barrier layer 508 prevents the underlying aluminum metal layer 506 from forming hillocks when under exposed to high temperature processes. Furthermore, aluminum nitride layer 508 does not react with the underlying aluminum metal layer 506, thereby preventing alloy formation at the interface as compared to conventional structures, resulting in reduced aluminum metal line contact resistance. In one embodiment, the nitrogen element included in the aluminum nitride barrier layer 505 may have a ratio between about 5 percent by atomic weight and about 30 percent by atomic weight, for example, about 10 percent by atomic weight.

At the beginning of barrier layer sputtering deposition step 408, the first gas mixture and the flow rate of the first gas mixture at step 406 may be smoothly transition into the second gas mixture and gas flow rate regulated at step 408, or remain substantially the same, as the manner controlled between optional step 404 to step 406. The transition between steps 404, 406, 408 may be alternatively configured. The on-and-off of the reactive gas supplied at optional step 404 and step 408 facilitates integratedly depositing the optional barrier 505 and the upper barrier layer 508 within a singe processing chamber, thereby reducing manufacturing cost and overall process time. Additionally, as the optional barrier layer 505, the metal layer 506 and the barrier layer 508 are both formed from the same target source material, the films 505, 506, 508 are highly comparable to each other, thereby providing a good adhesion at their interface.

In one embodiment, the reactive gas in the second gas mixture may be varied during processing to adjust the film properties of the barrier layer 508. Different film properties of the barrier layer 508 provide different etching rate, passivation capability and contact resistivity to meet different process requirements. For example, in the embodiment where a dielectric-dominated film is desired to provide a good passivation the aluminum metal layer 506, a higher flow rate of nitrogen containing reactive gas may be supplied in the second gas mixture to provide the aluminum nitride layer 508 with a higher ratio of nitrogen to aluminum. In another example, in the embodiment where a gradient second layer is desired which has a metallic-dominated region to maintain low contact resistance at the interface with the underlying metal layer 506 and a dielectric-dominated region on top for passivation, the nitrogen containing reactive gas in the second gas mixture may be increased during sputter depositing to adjust the amount of the nitrogen present across the thickness of the second layer 508. The metallic-dominated region at the interface with the underlying metal layer also alters the etching rate of underlying metal layer, thereby providing an alternative manner for adjusting etching selectivity. In contrast, the gas flow control of the reactive gas may be gradually reduced to create a different film structure with different desired film properties. The change in reaction gas may alternatively be changed step-wise or in another manner. It is noted that the manner as described for adjusting the film properties of barrier layer 508 may also be utilized to adjust the film properties of the optional barrier layer 505 to meet different process requirements.

Additionally, in embodiments where the barrier layer 508 is desired to have a quite different etch rate from the underlying metal layer 506, a high flow rate of the nitrogen containing reactive gas may be supplied in the second gas mixture, thereby creating a high etching selectivity of the barrier layer 508 to the metal layer 506. The high etching selectivity of the barrier layer 508 to the metal layer 506 facilitates a good etch stop point for the subsequent patterning etching process, thereby forming a desired structure on the substrate and preventing undercut defects present during etching process, resulting in a controlled profile of the etched film stack.

As the process may be performed to form different interconnection structure in the transistor, such as gate electrode layer or source/drain contact layers, the nitrogen concentration provided by the reactive gas in the second gas mixture at step 408 or optional step 404 may be varied to form different barrier layer 508 or optional barrier layer 505 with different film properties to meet different device performance requirements.

In one embodiment, the reactive and inert gas supplied in the second gas mixture are N₂ gas and Ar gas respectively. The N₂ gas may be supplied at a flow rate between about 30 sccm and about 180 sccm, such as between about 45 sccm and about 120 sccm, for example between about 60 sccm and about 90 sccm. The Ar gas may be supplied at a flow rate between about 50 sccm and about 300 sccm, such as between about 75 sccm and about 200 sccm, for example between about 100 sccm and about 150 sccm.

Process parameters may be regulated the same as the parameters at optional step 404 and step 406 while supplying the preliminary and the first gas mixture and applying the DC power. Alternatively, the process parameters, such as spacing or bias power, may be changed at step 408 while supplying the second gas mixture to meet different process requirements.

In one embodiment, the optional barrier layer 505, the metal layer 506 and the second barrier layer 508 may be integratedly deposited in a single chamber, such as the processing chamber 300 in FIG. 3, without breaking vacuum. The triple layer structure provides the upper barrier layer 508 and the lower barrier layer 505 sandwiching the metal layer 506, thereby preventing the metal layer 506 from upwardly or downwardly growing hillocks at the interface. Moreover, as the upper 508 and the lower barrier layer 505 are formed as aluminum nitride dielectric layers, the aluminum nitride dielectric layers will not form the undesired alloy with the metal layer 506 while experiencing subsequent high temperature deposition process as conventional techniques, thereby reducing contact resistance and improving surface uniformity. Additionally, the different film properties of the aluminum nitride dielectric layer and the aluminum metal layer provide good etch selectivity for subsequent patterning processes. It is contemplated that the triple layer structure may be formed in different metal interconnection structures in other devices. Additionally, the triple layer structure may be formed on any different substrates, including those having an existing barrier layer disposed thereon, such as Mo, Cr, Ta, Ti, or W.

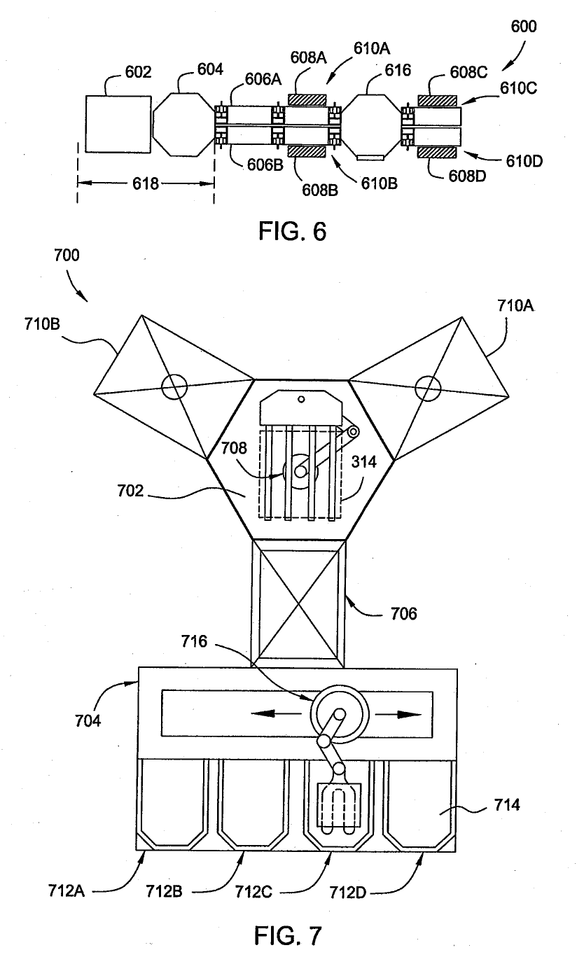

In an specific exemplary embodiment depicted in the present application while the optional step 404 is not performed, the metal layer 506, such as an aluminum layer (Al), may be deposited on a pre-disposed barrier layer 504, such as a molybdenum layer (Mo), on the substrate 304. It is contemplated that the pre-disposed barrier layer 504 may also be other material, such as molybdenum nitride (MoN) layer suitable for forming the gate electrode. Subsequently, the barrier layer 508, an aluminum nitride (AlN) layer, is deposited on the aluminum metal layer 506. The aluminum metal layer 506 and the barrier layer 508 may be integratedly deposited on a single chamber, such as the chamber 300, disposed in a cluster system. Furthermore, the pre-disposed barrier layer 504 may be formed in a second chamber integrated in the cluster system where the chamber 300 is incorporated, which will be further described with reference to FIGS. 6 and 7. Therefore, the while film stack for forming the gate structure may be integrated in a cluster system, thereby reducing overall process cycle time and manufacture cost.

FIG. 6 depicts a top plan view of one embodiment of a cluster system 600 that may be used to perform one embodiment of the present invention. The cluster system 600 includes a factory interface 618 having a swing module 602 coupled to an atmospheric rotation module 604. The atmospheric rotation module 604 is coupled to a plurality of process chambers 610A-D and a vacuum rotation module 616 through a load lock chamber 606 (shown as 606A-B). Typically, the vacuum rotation module 616 is maintained at a vacuum condition to eliminate the necessity of adjusting the pressures between the vacuum rotation module 616 and the individual process chambers 610A-D after each substrate transfer. In one embodiment, at least one or more of the process chambers 610A-D is a physical vapor deposition chamber, such as the process chamber 300 as depicted in FIG. 3. It is noted that the numbers of the process chambers 610A-D installed in the cluster system 600 may be varied to meet different process requirements. The process chambers 610A-D may each have targets 608A-D with different materials to facilitate depositing different metal containing material on the substrate 314.

In operation, the substrate 314 is positioned to lay on the swing module 602 in a plane parallel to the ground. Subsequently, the substrate 314 is transferred into the atmospheric rotation module 604 to rotate the substrate 314 up about 90 degrees to a vertical position relative to the ground to transfer to the load lock chamber 606A-B. The substrate 314 is subsequently transferred into either one of the chambers 608A-B to perform a first deposition process. In a certain embodiments where the substrate 314 is transferred through the load lock chamber 606B to the process chamber 610B to perform the first deposition process, the substrate 314 having a surface facing the target 608B is thereby deposited a first film on the substrate surface. After the first deposition process is performed on the substrate 314, the substrate 314 may be further transfer to the process chambers 608C-D through the vacuum rotation module 616 to perform a second deposition process. The substrate 314 is kept in its vertical position while entering the vacuum rotation module 616 and rotated about 180 degrees in a circular motion to have the substrate 314 readily to be transferred to the process chamber 610C. The substrate rotation in the vacuum rotation module 616 allows the substrate surface having the first film disposed thereon to be rotated to face the target 608C disposed in the process chamber 610C while entering to the process chamber 610C, thereby facilitating depositing the second film on the desired substrate surface.

In an exemplary embodiment depicted in the present invention, the substrate 314 is transferred to either one of the process chamber 610A-B having a molybdenum target disposed thereon to deposit a molybdenum (Mo) layer on the substrate 314. Subsequently, the substrate 314 is rotated in the vacuum rotation module 616 and further transferred into either one of the process chamber 610D-C having a aluminum target to deposit an aluminum (Al) layer and an aluminum nitride layer on the aluminum layer, using the method 400 as described in FIG. 4. It is noted that the substrate 314 may be transferred between the processing chambers 610A-D in any order or as many times as needed to form different structures on the substrate 314.

FIG. 7 depicts a top plan view of another embodiment of a cluster system 700 suitable for manufacturing the gate electrode for TFT transistors on large area substrates, such as the substrate 314 depicted in FIG. 4, using the method of FIG. 4. The cluster system 700 includes a transfer chamber 702 coupled to a factory interface 704 by a load lock chamber 706. The transfer chamber 702 has at least one vacuum robot 708 disposed therein that is adapted to transfer substrates between a plurality of circumscribing process chambers 710A-B and the load lock chamber 706. In one embodiment, at least one or more of the process chambers 710A-B is a physical vapor deposition chamber, such as the process chamber 300 as depicted in FIG. 3. The process chambers 710A-B may each have targets with different materials to facilitate different metal containing material on the substrate 314. The factory interface 704 generally includes a plurality of substrate storage cassettes 714 and at least one atmospheric robot 716. The cassettes 714 are generally removably disposed in a plurality of bays 712 (shown as 712A-D) formed on one side of the factory interface 704. The atmospheric robot 716 is adapted to transfer substrates 314 between the cassettes 714 and the load lock chamber 716. Typically, the factory interface 704 is maintained at or slightly above atmospheric pressure.

In operation, the substrate 314 may be transferred by the atmospheric robot 716 positioned in the factory interface 704 from the cassette 714 to the load lock chamber 706. The vacuum robot 708 is subsequently transferred the substrate 314 from the load lock chamber 706 to one of the processing chamber 710A-B to deposit a desired layer on the substrate 314. In an exemplary embodiment depicted in the present invention, the substrate 314 is transferred to the process chamber 710A to deposit a molybdenum (Mo) on the substrate 314 and subsequently, the substrate 314 is further transferred to the process chamber 714B to deposit an aluminum (Al) layer and an aluminum nitride layer on the aluminum layer, using the method as described in FIG. 4. It is noted that the substrate 314 may be transferred between the processing chamber 714A-B in any order or as many times as needed to form different structures on the substrate 314. It is noted that the processing chambers 714A-B may be configured in a horizontal in-line flow manner (e.g., the processing chamber 714A-B are coupled in sequence from the load lock chamber 702) to facilitate depositing the gate electrode on the substrate 314 directly between chambers 714A-B in a linear transfer movement without moving through the transfer chamber 702. The in-line flow configuration may be adapted in any other cluster systems, including those from other manufacturers, to practice the present invention. One example of the cluster system that may be applicable to the present invention is a sputter system, available from ULVAC Technologies, Inc., located in Methuen, Mass.

Thus, methods for forming a metal interconnection structure suitable for thin-film transistor applications are provided. The method advantageously produces interconnection film stack having good etching selectivity, low contact resistance, and good surface roughness, thereby improving electrical performance for devices, such as transistors. Additionally, the interconnection film stack may be formed in a single chamber without breaking vacuum, thereby reducing manufacturing cost and overall process cycle time.

While the foregoing is directed to embodiments of the present invention, other and further embodiments of the invention may be devised without departing from the basic scope thereof, and the scope thereof is determined by the claims that follow.

What is claimed is:

1. A method of forming a metal interconnection structure in thin-film transistor applications, comprising:
providing a substrate into a processing chamber configured to form a metal interconnection structure for TFT devices thereon;
supplying a first gas mixture into the chamber to deposit a metal layer on the substrate; and
supplying a second gas mixture into the chamber to deposit a barrier layer on the metal layer.

2. The method of claim 1, wherein the step of supplying the first gas mixture further comprises:
sputtering source material from a target disposed in the processing chamber; and
reacting the sputtered material with the first gas mixture to form the metal layer on the substrate.

3. The method of claim 2, wherein the source material is at least one of Al or Al alloy.

4. The method of claim 3, wherein the metal layer is aluminum layer.

5. The method of claim 1, wherein the metal layer is deposited on a pre-disposed barrier layer formed on the substrate.

6. The method of claim 5, wherein the pre-disposed barrier layer is formed from a material selected from a group consisting of molybdenum (Mo), chromium (Cr), titanium (Ti), tantalum (Ta), tungsten (W), zinc (Zn), tin (Sn), molybdenum nitride, chromium nitride, titanium nitride, tantalum nitride, tungsten nitride, aluminum nitride, zinc nitride and combination thereof.

7. The method of claim 1, wherein the step of supplying the first gas mixture further comprises:
supplying the first gas mixture selected from a group consisting of Ar, He and Kr.

8. The method of claim 1, wherein the step of supplying the second gas mixture further comprises:
supplying a reactive gas and an inert gas in the second gas mixture.

9. The method of claim 8, wherein the reactive gas is selected from a group consisting of N₂, N₂O, NO₂, NH₃, and the inert gas is selected from a group consisting of Ar, He and Kr.

10. The method of claim 8, wherein the step of supplying the reactive gas in the second gas mixture further comprises:
sputtering source material from a target disposed in the processing chamber; and
reacting the sputtered material with the reactive gas in the second gas mixture to form the barrier layer on the substrate.

11. The method of claim 10, wherein the barrier layer is an aluminum nitride layer.

12. The method of claim 1, wherein the step of supplying the first gas mixture further comprises:
supplying a preliminary gas mixture into the processing chamber to form a underlying barrier layer on the substrate prior to supplying the first gas mixture.

13. The method of claim 12, wherein the step of supplying the preliminary gas mixture further comprises:
supplying a reactive gas and an inert gas in the preliminary gas mixture.

14. The method of claim 13, wherein the reactive gas is selected from a group consisting of N₂, N₂O, NO₂, NH₃ and the inert gas is selected from a group consisting of Ar, He and Kr.

15. The method of claim 12, wherein the underlying barrier layer is an aluminum nitride layer.

16. A method of forming a metal interconnection structure in thin-film transistor applications, comprising:
providing a substrate into a processing chamber;
supplying a first gas mixture into the chamber;
sputtering source material from a target disposed in the processing chamber using the first gas mixture;
reacting the sputtered material with the first gas mixture to form a metal layer on the substrate;
supplying a second gas mixture into the chamber;
sputtering source material from the target disposed in the processing chamber using the second gas mixture; and
reacting the sputtered material with the second gas mixture to form a barrier layer on the metal layer.

17. The method of claim 16, further comprising:
forming a underlying barrier layer on the substrate in the processing chamber prior to depositing the metal layer.

18. The method of claim 16, wherein the substrate has a barrier layer underlying on the substrate, wherein the pre-disposed barrier layer is formed from a material selected from a group consisting of molybdenum (Mo), chromium (Cr), titanium (Ti), tantalum (Ta), tungsten (W), zinc (Zn), tin (Sn), molybdenum nitride, chromium nitride, titanium nitride, tantalum nitride, tungsten nitride, aluminum nitride, zinc nitride and combination thereof.

19. The method of claim 16, wherein the first gas mixture is selected from a group consisting of Ar, He and Kr.

20. The method of claim 20, wherein the second gas mixture including a reactive gas and an inert gas, wherein the reactive gas is selected from a group consisting of N₂, N₂O, NO₂, NH₃ and the inert gas is selected from a group consisting of Ar, He and Kr.

21. A metal interconnection structure utilized to form a gate electrode layer in a thin-film transistor, comprising:
a substrate;
a first barrier layer disposed on the substrate;
a metal layer disposed on the substrate in a processing chamber;
a second barrier layer disposed on the metal layer formed in the processing chamber, wherein the first barrier layer, the metal layer and the second barrier layer are configured to form a metal interconnection structure for TFT devices.

22. The method of claim 21, wherein the first barrier layer is formed from a material selected from a group consisting of molybdenum (Mo), chromium (Cr), titanium (Ti), tantalum (Ta), tungsten (W), zinc (Zn), tin (Sn), molybdenum nitride, chromium nitride, titanium nitride, tantalum nitride, tungsten nitride, aluminum nitride, zinc nitride and combination thereof.

23. The method of claim 21, wherein the first barrier layer is formed in the processing chamber.

24. The method of claim 21, wherein the metal layer is an aluminum layer.

25. The method of claim 21, wherein the second barrier layer is an aluminum nitride layer.
